(19) United States
(12) Patent Application Publication
(10) Pub. No.: US 2025/0089467 A1
(43) Pub. Date: Mar. 13, 2025

(54) DISPLAY PANEL AND METHOD FOR PRODUCING THE SAME

(71) Applicants: Mianyang HKC Optoelectronics Technology Co., Ltd., Mianyang (CN); HKC CORPORATION LIMITED, Shenzhen (CN)

(72) Inventors: Chuan WU, Mianyang (CN); Dongmei WEI, Mianyang (CN); Zhonglin CAO, Mianyang (CN); Yao LI, Mianyang (CN); Haijiang YUAN, Mianyang (CN)

(73) Assignees: Mianyang HKC Optoelectronics Technology Co., Ltd., Mianyang (CN); HKC CORPORATION LIMITED, Shenzhen (CN)

(21) Appl. No.: 18/822,337

(22) Filed: Sep. 2, 2024

(30) Foreign Application Priority Data
Sep. 13, 2023 (CN) 202311183553.0

(51) Int. Cl. H10K 59/122; H10K 59/12; H10K 59/80

(52) U.S. Cl. CPC H10K 59/122; H10K 59/1201; H10K 59/873

(57) ABSTRACT

The present disclosure provides a display panel, including: conductive isolation structures arranged on a pixel definition layer and each surrounding one of pixel accommodation areas; each of the conductive isolation structures including a main structure and a top structure located on an upper surface of the main structure and shielding the main structure; a portion of the top structure extending beyond the upper surface of the main structure being defined as an overhanging part; an encapsulating layer covering sub-pixels and extending along sidewalls of the conductive isolation structures to form grooves surrounded by the encapsulating layer; an area directly below the overhanging part and located in one of the grooves being defined as a shielding area; a plurality of insulating spherical structures at least filling the shielding area to support the overhanging part. The present disclosure also provides a method for producing the display panel.

### CROSS REFERENCE TO RELATED APPLICATIONS

The present disclosure claims priority to Chinese patent application No. 202311183553.0 filed on Sep. 13, 2023, the entire contents of which are incorporated herein by reference.

### TECHNICAL FIELD

The present disclosure relates to the field of display technologies, and in particular to a display panel and a method for producing the display panel.

### BACKGROUND

In order to achieve high resolution and colorization of OLED (organic light-emitting diode) and better solve the problems of low resolution of cathode template and low yield of devices, a cathode isolation column structure is introduced in the actual research, that is, instead of using a metal mask in the production of the device, an insulating partition is made on a substrate before forming an organic film and a metal cathode on the substrate by evaporation, and finally different pixels of the device are separated to form a pixel array.

The cathode isolation column structure includes a conductive structure and an insulating structure, and the conductive structure overlaps with the cathode. Since partial structure of the insulation structure is suspended, a film layer of the suspended structure is prone to the possibility of falling off or collapsing during the packaging process. The broken film layer may puncture the cathode, causing the cathode to break at the portion where the cathode overlaps with the conductive structure, affecting the entire surface connectivity of the cathode.

### SUMMARY OF THE DISCLOSURE

The present disclosure provides a display panel and a method for producing the display panel.

In one aspect, the present disclosure provides a display panel, including: a driving substrate; a pixel definition layer, arranged on the driving substrate and protruding from the driving substrate to form pixel accommodation areas; conductive isolation structures, arranged on the pixel definition layer and each surrounding one of the pixel accommodation areas, each of the conductive isolation structures includes a main structure and a top structure located on an upper surface of the main structure and shielding the main structure, and a portion of the top structure extending beyond the upper surface of the main structure is defined as an overhanging part; sub-pixels, arranged in the pixel accommodation areas and located between the conductive isolation structures; and an encapsulating layer, covering the sub-pixels and extending along sidewalls of the conductive isolation structures to form grooves surrounded by the encapsulation layer. An area directly below the overhanging part and located in one of the grooves is defined as a shielding area; the display panel includes a plurality of insulating spherical structures, at least partial insulating spherical structures are arranged in the groove, and the plurality of insulating spherical structures at least fill the shielding area to support the overhanging part.

In another aspect, the present disclosure provides a method for producing the display panel according to the first technical solution, and the method includes: providing a driving substrate, wherein a pixel definition layer, conductive isolation structures, sub-pixels, and an encapsulating layer are arranged on the driving substrate; the pixel definition layer protrudes from the driving substrate to form pixel accommodation areas; the conductive isolation structures are arranged on the pixel definition layer and each surrounds one of the pixel accommodation areas; each of the conductive isolation structures comprises a main structure and a top structure located on an upper surface of the main structure and shielding the main structure; a portion of the top structure extending beyond the upper surface of the main structure is defined as an overhanging part; the sub-pixels are arranged in the pixel accommodation areas and are located between the conductive isolation structures; the encapsulating layer covers the sub-pixels and extends along sidewalls of the conductive isolation structures to form grooves surrounded by the encapsulating layer; an area directly below the overhanging part and located in one of the grooves is defined as a shielding area; and disposing at least partial of a plurality of insulating spherical structures in one of the grooves, and enabling the plurality of insulating spherical structures at least fill the shielding area to support the overhanging part.

### BRIEF DESCRIPTION OF THE DRAWINGS

In order to more clearly illustrate the technical solutions in the embodiments of the present disclosure, the drawings needed to be used in the description of the embodiments will be briefly introduced below. Obviously, the drawings in the following description are only some embodiments of the present disclosure. For those skilled in the art, other drawings may also be obtained based on these drawings without making any creative efforts.

FIG. 1 is a schematic structural view of a display panel according to a first embodiment of the present disclosure.

FIG. 2 is a schematic structural view of a display panel according to a second embodiment of the present disclosure.

FIG. 3 is a schematic structural view of a display panel according to a third embodiment of the present disclosure.

FIG. 4 is a schematic flow chart of a method for producing a display panel according to an embodiment of the present disclosure.

FIG. 5 is a schematic structural view corresponding to block S10 and block S20 shown in FIG. 4 according to an embodiment of the present disclosure.

FIG. 6 is a schematic structural view corresponding to block S10 and block S20 shown in FIG. 4 according to another embodiment of the present disclosure.

### DETAILED DESCRIPTION

The solutions in the embodiments of the present disclosure will be described in detail below with reference to the accompanying drawings.

In the following description, specific details such as specific system structures, interfaces, technologies, etc. are provided for the purpose of explanation but not limitation, so as to provide a thorough understanding of the present disclosure.

The technical solutions in the embodiments of the present disclosure will be clearly and completely described below in combination with the accompanying drawings in the embodiments of the present disclosure. Obviously, the described embodiments are merely parts of the embodiments of the present disclosure, rather than all of the embodiments. Based on the embodiments of the present disclosure, any other embodiments obtained by those skilled in the art without creative efforts fall within a protection scope of the present disclosure.

The terms “first”, “second”, and “third” in the present disclosure are merely intended for a purpose of description, and shall not be understood as indicating or implying relative significance or implicitly indicating the quantity of indicated technical features. Therefore, features defined with “first”, “second”, and “third” may explicitly or implicitly include at least one of the features. In the description of the present disclosure, “plurality” means at least two, such as two, three, etc., unless otherwise clearly and specifically limited. All directional indications (such as up, down, left, right, front, back . . . ) in the embodiments of the present disclosure are only configured to explain relative positional relationships, movement situations, etc., between various components in a specific posture (as shown in the drawings). If the specific posture changes, the directional indications change accordingly. In addition, the terms “include” and “have”, and any variations thereof are intended to cover non-exclusive inclusion. For example, a process, method, system, product, or device that includes a series of steps or units is not limited to the listed steps or units, and instead, further optionally includes unlisted steps or units, or further optionally includes other steps or units inherent to the process, method, product, or device.

The term “embodiment” mentioned in the specification means that particular features, structures, or characteristics described with reference to the embodiment may be included in at least one embodiment of the present disclosure. This phrase appearing in various positions in the specification does not necessarily refer to the same embodiment, nor is it an independent or alternative embodiment mutually exclusive with other embodiments. Those skilled in the art explicitly or implicitly understand that the embodiments described in the specification may be combined with other embodiments.

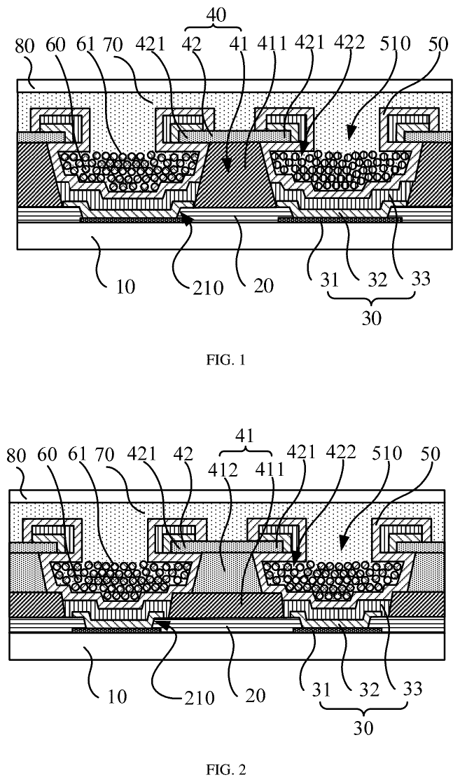

As shown in FIG. 1, FIG. 1 is a schematic structural view of a display panel according to a first embodiment of the present disclosure.

The present disclosure provides a display panel. The display panel includes a driving substrate 10, a pixel definition layer 20, conductive isolation structures 40, sub-pixels 30, and an encapsulating layer 50. The pixel definition layer 20 is arranged on the driving substrate 10. The pixel definition layer 20 protrudes from the driving substrate 10 to form pixel accommodation areas 210. The conductive isolation structures 40 are arranged on the pixel definition layer 20 and each surrounds one of the pixel accommodation areas 210. Each of the conductive isolation structures 40 includes a main structure 41 and a top structure 42 located on an upper surface of the main structure 41 and shielding the main structure 41. A portion of the top structure 42 extending beyond the upper surface of the main structure 41 is defined as an overhanging part 421. The sub-pixels 30 are arranged in the pixel accommodation areas 210 and are located between the conductive isolation structures 40. The encapsulating layer 50 covers the sub-pixels 30 and extends along sidewalls of the conductive isolation structures 40 to form grooves 510 surrounded by the encapsulating layer 50. An area directly below the overhanging part 421 and located in one of the grooves 510 is defined as a shielding area 422. The display panel also includes a plurality of insulating spherical structures 60, at least partial insulating spherical structures 60 are arranged within the groove 510. The plurality of insulating spherical structures 60 at least fill the shielding area 422 to support the overhanging part 421.

In the present disclosure, the insulating spherical structures 60 are filled directly below the overhanging part 421 of the conductive isolation structure 40 to support the overhanging part 421, preventing a cathode 33 directly below the overhanging part 421 from being punctured due to a film layer of the overhanging part 421 falling off or collapsing during the packaging process of the display panel, causing the cathode 33 to break at the portion where the cathode 33 overlaps with the conductive isolation structure 40, thus affecting the entire surface connectivity of the cathode 33.

The driving substrate 10 is configured to drive the sub-pixels 30 to emit light.

Each of the sub-pixels 30 includes an anode 31, a light-emitting layer 32, and a cathode 33. The anode 31, the light-emitting 32, and the cathode 33 are arranged in a stack. The cathode 33 is arranged between the light-emitting layer 32 and the encapsulating layer 50. There are multiple sub-pixels 30, and each of the sub-pixels 30 corresponds to a color pixel. There are multiple pixel accommodation areas 210 and each of the pixel accommodation areas 210 accommodates at least one sub-pixel 30.

The arrangement of the sub-pixels 30 is not limited in the present disclosure, and may be selected according to actual demands. The following description of the present disclosure mainly takes two adjacent sub-pixels 30 as an example.

In some embodiments, one pixel accommodation area 210 accommodates one sub-pixel 30.

The conductive isolation structures 40 are configured to isolate each of the sub-pixels 30. In some embodiments, the conductive isolation structures 40 separate the light-emitting layer 32 of each sub-pixel 30 from each other, and separates the cathode 33 of each sub-pixel 30 from each other, so as to avoid pixel crosstalk problems. The cathode 33 of each sub-pixel 30 is conductive to the conductive isolation structure 40, enabling the cathode 33 of each sub-pixel 30 to conductive to each other through the conductive isolation structure 40, so as to achieve a network connection of the cathode 33 between different sub-pixels 30, and realize the uniformity of the entire surface signal of the cathode 33.

The top structure 42 is located on the upper surface of the main structure 41 and shields the main structure 41. It can be understood that the top structure 42 is in contact with the main structure 41, and an orthographic projection of the top structure 42 on the driving substrate 10 completely covers an orthographic projection of the main structure 41 on the driving substrate 10. The overhanging part 421 is suspended relative to the main structure 41. When the light-emitting layer 32 and the cathode 33 are deposited by evaporation, the evaporation angle may be changed through the overhanging part 421 enabling the cathode 33 to cover the organic light-emitting layer 32, which is beneficial to the cathode 33 being in contact with and being conductive to the main structure 41.

There are multiple conductive isolation structures 40, and two adjacent conductive isolation structures 40 share a same side wall of the two adjacent conductive isolation structures 40, so as to ensure that a spacing between every two sub-pixels 30 is equal, which is beneficial to the uniformity of display. In some embodiments, the conductive isolation structures 40 are rectangular annular structures, and multiple conductive isolation structures 40 are arranged in an array. In a row direction or column direction of the array of the conductive isolation structures 40, two adjacent conductive isolation structures 40 share the same side wall of the two adjacent conductive isolation structures 40.

The encapsulating layer 50 extends along the sidewalls of the conductive isolation structures 40 to form the grooves 510 surrounded by the encapsulating layer 50. It can be understood that the encapsulating layer 50 covers the sidewalls of the conductive isolation structures 40 and the sub-pixels 30. The encapsulating layer 50 covering the sidewalls of the conductive isolation structures 40 means that the encapsulating layer 50 covers a sidewall of the main structure 41, a sidewall of the top structure 42, and a lower surface of the overhanging part 421. The encapsulating layer 50 is configured to protect the sub-pixels 30 during the process of producing the display panel. The encapsulating layer 50 includes a non-conductive inorganic material. In some embodiments, the encapsulating layer 50 includes a silicon-containing inorganic material, such as a SiNx-based inorganic material, and the x is a non-zero natural number.

A portion of the encapsulating layer 50 covering the sidewalls of the conductive isolation structures 40 serves as sidewalls of the grooves 510, and a portion of the encapsulating layer 50 covering the sub-pixels 30 serves as bottom walls of the grooves 510. The grooves 510 are pot-shaped. Notches of the grooves 510 face toward a side away from the driving substrate 10.

The encapsulating layer 50 also extends to an upper surface of top structure 42. That is to say, the encapsulating layer 50 not only covers the sidewalls of the conductive isolation structures 40, but also covers part of the upper surface of the top structure 42. It should be understood that, during the process of depositing the cathode 33 and the light-emitting layer 32 on the upper surface of the anode 31 by evaporation, a part of the light-emitting layer 32 and a part of the cathode 33 are successively stacked on the sidewall of the top structure 42, and are successively stacked on the upper surface of the top structure 42. The encapsulating layer 50 covers the part of the upper surface of the top structure 42, and also covers the cathode 33 located on the upper surface of the top structure 42 and the cathode 33 located on the sidewall of the top structure 42, thereby also covering the light-emitting layer 32 located on the upper surface of the top structure 42 and the light-emitting layer 32 located on the sidewall of the top structure 42.

The display panel also includes an organic encapsulating layer 70 filling gaps between the insulating spherical structures 60 and the grooves 510, and covering the encapsulating layer 50 and the conductive isolation structures 40. A side of the organic encapsulating layer 70 away from the driving substrate 10 is flattened to ensure the coating uniformity of other encapsulating layers and meet the overall packaging requirements. The organic encapsulating layer 70 fills the gaps between the insulating spherical structures 60 and may fix the insulating spherical structures 60, prevent the insulating spherical structures 60 from being displaced, and affect the supporting effect on the shielding area 422.

The organic encapsulating layer 70 includes an organic acrylic material. It should be understood that, the organic encapsulating layer 70 may also be made of other materials, which is not limited here and may be selected according to actual demands.

The plurality of insulating spherical structures 60 may be partially located in the groove 510, or may be entirely located in the groove 510.

The plurality of insulating spherical structures 60 located in the groove 510 are accumulated to form an accumulation layer 61. An upper surface of the accumulation layer 61 is lower than a surface of the encapsulating layer 50 located on the upper surface of the top structure 42 away from a side surface of the pixel definition layer 20, and is higher than a surface of the encapsulating layer 50 located on the lower surface of the top structure 42 close to the side surface of the pixel definition layer 20.

The upper surface of the accumulation layer 61 is lower than the surface of the encapsulating layer 50 located on the upper surface of the top structure 42 away from the side surface of the pixel definition layer 20, so as to prevent the accumulation layer 61 from being too high, causing the thickness of the organic encapsulating layer 70 to be too large, which is not conducive to a production of a thin display panel, and wastes materials.

The upper surface of the accumulation layer 61 is higher than the surface of the encapsulating layer 50 located on the lower surface of the top structure 42 close to the side surface of the pixel definition layer 20, so as to ensure that the plurality of insulating spherical structures 60 located in the groove 510 may fully fill the shielding area 422, better support the overhanging part 421, and prevent the cathode 33 below the overhanging part 421 from being punctured due to the film layer of the overhanging part 421 falling off or collapsing during the packaging process of the display panel, causing the cathode 33 to break at the portion where the cathode 33 overlaps with the conductive isolation structure 40, thus affecting the entire surface connectivity of the cathode 33.

The insulating spherical structures 60 include alumina-based ceramic particles. The insulating spherical structures 60 have high transparency and high strength, enabling the insulating spherical structures 60 to support the overhanging part 421, while the insulating spherical structures 60 will not shield the light emitted by the sub-pixels 30, thereby not affecting the normal display of the display panel. The insulating spherical structures 60 are arranged into spherical shapes, and when filling the shielding area 422, the rolling property of the insulating spherical structures 60 may be configured to autonomously fill the shielding area 422, thereby facilitating the filling of the insulating spherical structures 60.

The diameter of each of the insulating spherical structures 60 is smaller than a minimum depth of the groove 510 and smaller than the width of the notch of the groove 510. The minimum depth of the groove 510 is a distance between a part of the encapsulating layer 50 covering the lower surface of the overhanging part 421 and a part of the encapsulating layer 50 directly opposite the part of the encapsulating layer 50 covering the lower surface of the overhanging part 421. The diameter of each of the insulating spherical structures 60 is smaller than the minimum depth of the groove 510, so as to ensure that the insulating spherical structures 60 may enter the shielding area 422 to support the overhanging part 421. The diameter of each of the insulating spherical structures 60 is smaller than the width of the notch of the groove 510, so as to ensure that the insulating spherical structures 60 may enter the groove 510 from the notch.

The insulating spherical structures 60 filling the shielding area 422 may not only support the overhanging part 421, enabling the film layer of the overhanging part 421 to be not easy to fall off or collapse, but also protect the part of the encapsulating layer 50 located in the shielding area 422 and covering the cathode 33, enabling the insulating spherical structures 60 to disperse stress when the stress is generated, thereby reducing the probability of broken of the encapsulating layer 50, and then effectively protecting the cathode 33 below the shielding area 422.

It should be noted that, the shielding area 422 accommodates at least one insulating spherical structure 60.

In some embodiments, the plurality of insulating spherical structures 60 are all located in the grooves 510, and the shielding area 422 accommodates multiple insulating spherical structure 60, enabling the multiple insulating spherical structures 60 to better disperse a force on the insulating spherical structures 60 exerted by the overhanging part 421 and provide better supports.

In some embodiments, the main structure 41 includes a conductive structure 411. A side wall of the conductive structure 411 is obliquely arranged with the overhanging part 421, and an inclination angle between the side wall of the conductive structure 411 and a lower surface of the overhanging part 421 is less than 90 degrees. That is to say, a longitudinal section of the side wall of the conductive structure 411 in a direction perpendicular to the driving substrate 10 is trapezoidal, and the cross-section of the side wall of the conductive structure 411 gradually decreases in a direction approaching the top structure 42.

The top structure 42 includes at least one of SiO₂, SiNx, and SiNO. The top structure 42 may also be of other insulating materials. The x is a non-zero natural number.

It should be understood that, the main structure 41 needs to support the top structure 42 above, so that a cross-sectional width of one end of the main structure 41 in contact with the top structure 42 (i.e., an upper end of the conductive structure 411) in the direction perpendicular to the driving substrate 10 may not be too small, otherwise the main structure 41 is insufficient to support the top structure 42. Therefore, the cross-sectional width of the end of the main structure 41 in contact with the top structure 42 needs to meet a certain value. In response to the cross-sectional width of the end of the main structure 41 in contact with the top structure 42 being a fixed value, the greater the inclination angle between the side wall of the conductive structure 411 and the lower surface of the overhanging part 421, the better the support effect of the conductive structure 411 on the top structure 42, the lower probability of the cathode 33 to break at the portion where the cathode 33 in contact with the conductive structure 411. But the steeper the slope of the side wall of the conductive structure 411, the greater the difficulty of film-forming of the encapsulating layer 50 covering the side wall of the conductive structure 411, reducing the adhesion and strength of the encapsulating layer 50.

In the present disclosure, the insulating spherical structures 60 are arranged in the shielding area 422 to support the overhanging part 421, thereby bearing part of the supporting force for the main structure 41, enabling the cross-sectional width of the end of the main structure 41 in contact with the top structure 42 in the direction perpendicular to the driving substrate 10 to be appropriately reduced compared with that when the insulating spherical structures 60 are not arranged, then the inclination angle between the side wall of the conductive structure 411 and the lower surface of the overhanging part 421 is reduced, and the slope of the side wall of the conductive structure 411 becomes gentler. The difficulty of film-forming of the encapsulating layer 50 covering the side wall of the conductive structure 411 is reduced, and the strength of the encapsulating layer 50 and the adhesion of the encapsulating layer 50 to the side wall of the conductive structure 411 may be significantly improved. Meanwhile, a contact surface between the conductive structure 411 and the top structure 42 decreases, enabling the width of the overhanging part 421 relative to the end of the conductive structure 411 close to the top structure 42 to become longer, resulting in an increase in the controllability of the evaporation angle of the light-emitting layer 32 and the cathode 33 during evaporation deposition.

The cathode 33 is arranged in contact with and conductive to the conductive structure 411, that is to say, the cathode 33 is conductive through the conductive structure 411 of the main structure 41.

The display panel also includes an inorganic encapsulating layer 80 located on a side of the organic encapsulating layer 70 away from the driving substrate 10.

As shown in FIG. 1 and FIG. 2, FIG. 2 is a schematic structural view of a display panel according to a second embodiment of the present disclosure.

The structure of the display panel according to the second embodiment of the present disclosure is basically the same as the display panel according to the first embodiment of the present disclosure. The difference between the display panel according to the second embodiment of the present disclosure and the display panel according to the first embodiment of the present disclosure is that the main structure 41 of the display panel according to the second embodiment of the present disclosure also includes an intermediate structure 412 located between the conductive structure 411 and the top structure 42.

In some embodiments, the main structure 41 includes the conductive structure 411 and the intermediate structure 412, and the intermediate structure 412 is located between the conductive structure 411 and the top structure 42. A side wall of the intermediate structure 412 is obliquely arranged with the overhanging part 421, and an inclination angle between the side wall of the intermediate structure 412 and the lower surface of the overhanging part 421 is less than 90 degrees. That is to say, a longitudinal section of the side wall of the intermediate structure 412 in the direction perpendicular to the driving substrate 10 is trapezoidal, and the cross-section of the side wall of the intermediate structure 412 gradually decreases in the direction approaching the top structure 42. The cathode 33 is arranged in contact with and conductive to the conductive structure 411.

The material of the intermediate structure 412 may be the same as or different from the material of the top structure 42. In some embodiments, the intermediate structure 412 and the top structure 42 are made of the same material. The top structure 42 includes at least one of SiO₂, SiNx, and SiNO. The x is a non-zero natural number. The top structure 42 may also be of other insulating materials. Different etching rates of different materials are used to construct the shapes of the intermediate structure 412 and the top structure 42.

Similarly, with reference to the above description, it can be known that the insulating spherical structures 60 in the present disclosure are arranged in the shielding area 422 to support the overhanging part 421, enabling the insulating spherical structures 60 to bear part of the supporting force for the main structure 41, so as to appropriately reduce the cross-sectional width of the end of the main structure 41 in contact with the top structure 42 in the direction perpendicular to the driving substrate 10 compared with that when the insulating spherical structures 60 are not arranged, then the inclination angle between the side wall of the intermediate structure 412 and the lower surface of the overhanging part 421 is reduced, and the slope of the side wall of the intermediate structure 412 becomes gentler. The difficulty of film-forming the encapsulating layer 50 covering the side wall of the intermediate structure 412 is reduced, and the strength of the encapsulating layer 50 and the adhesion of the encapsulating layer 50 to the side wall of the intermediate structure 412 may be significantly improved. Meanwhile, a contact surface between the intermediate structure 412 and the top structure 42 decreases, enabling the width of the overhanging part 421 relative to the end of the intermediate structure 412 close to the top structure 42 to become longer, resulting in an increase in the controllability of the evaporation angle of the light-emitting layer 32 and the cathode 33 during evaporation deposition.

Compared with the display panel according to the first embodiment of the present disclosure, the intermediate structure 412 is arranged between the conductive structure 411 and the top structure 42 in this embodiment, enabling the height of the conductive structure 411 to be smaller, making it easier for the cathode 33 to overlap with the conductive structure 411.

It should be noted that the upper surface in the present disclosure refers to a surface away from the driving substrate 10, and the lower surface in the present disclosure refers to a surface close to the driving substrate 10.

It should be understood that the conductive isolation structure 40 of the present disclosure may also be other structures, as long as the top structure 42 shields the main structure 41 and the top structure 42 is partially suspended relative to the main structure 41 to form the overhanging part 421.

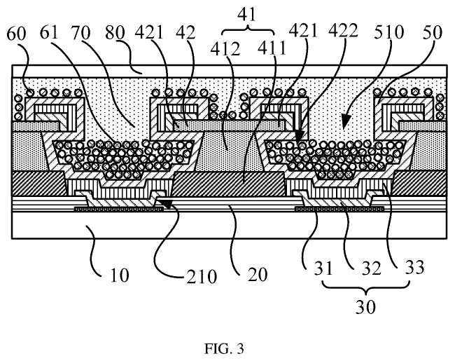

As shown in FIG. 1 to FIG. 3, FIG. 3 is a schematic structural view of a display panel according to a third embodiment of the present disclosure.

The structure of the display panel according to the third embodiment of the present disclosure is basically the same as the display panel according to the second embodiment of the present disclosure. The difference between the display panel according to the third embodiment of the present disclosure and the display panel according to the second embodiment of the present disclosure is that the plurality of insulating spherical structures 60 of the display panel according to the third embodiment of the present disclosure are partially located in the groove 510, and the density of the insulating spherical structures 60 within the accumulation layer 61 is greater than the density of the insulating spherical structures 60 located outside the groove 510.

In some embodiments, the plurality of insulating spherical structures 60 are partially located in the groove 510, and the density of the insulating spherical structures 60 within the accumulation layer 61 is greater than the density of the insulating spherical structures 60 located outside the groove 510.

It should be noted that the insulating spherical structures 60 and the organic encapsulating layer 70 in this embodiment are produced together. That is to say, the insulating spherical structures 60 are dispersed in the organic encapsulating layer 70 and are filled in the groove 510 together with the organic encapsulating layer 70. As a result, some of the insulating spherical structures 60 are located in the groove 510 and some of the insulating spherical structures 60 are located outside the groove 510. Due to the deposition of the insulating spherical structures 60 in the uncured organic encapsulating layer 70, the insulating spherical structures 60 located above the notch of the groove 510 are deposited in the groove 510, enabling the density of the insulating spherical structures 60 accumulated in the groove 510 to be greater than the density of the insulating spherical structures 60 located outside the groove 510.

Compared with the display panel according to the second embodiment of the present disclosure, the insulating spherical structures 60 filled in the shielding area 422 in this embodiment may also support the overhanging part 421.

The present disclosure provides a method for producing a display panel. The method for producing the display panel is configured to produce the display panel mentioned above.

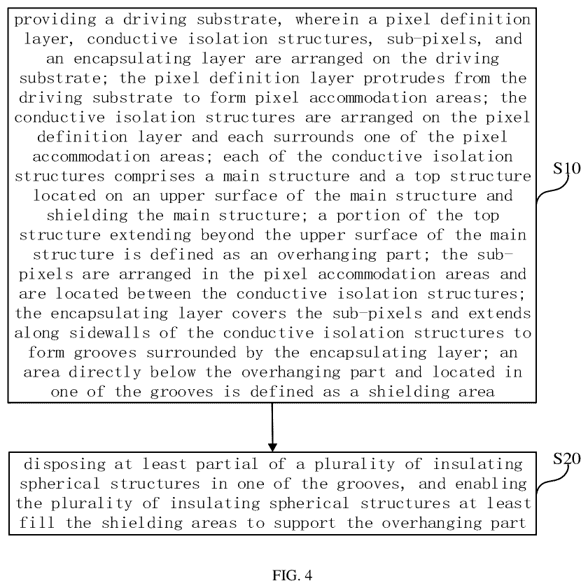

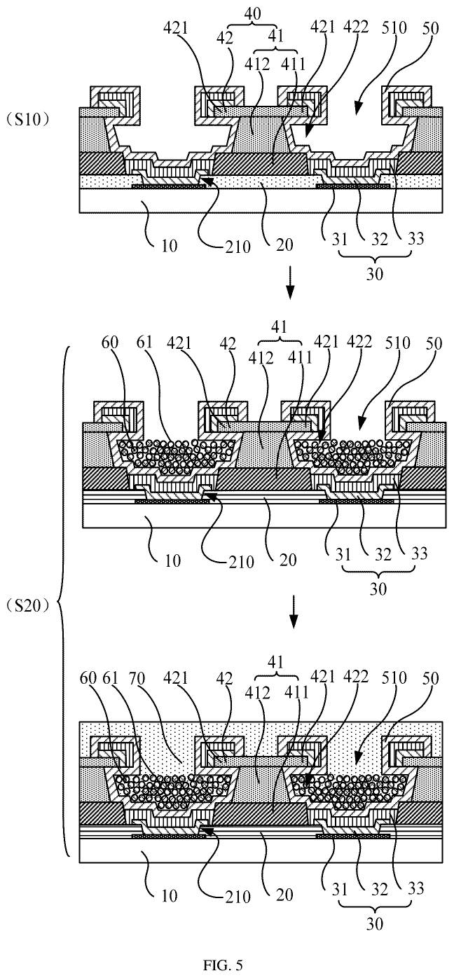

As shown in FIG. 2, FIG. 4 and FIG. 5, FIG. 4 is a schematic flow chart of a method for producing a display panel according to an embodiment of the present disclosure, FIG. 5 is a schematic structural view corresponding to block S10 and block S20 shown in FIG. 4 according to an embodiment of the present disclosure.

The method for producing the display panel may include operations executed by the following blocks.

At block S10, a driving substrate is provided. A pixel definition layer, a conductive isolation structure, sub-pixels, and an encapsulating layer are arranged on the driving substrate. The pixel definition layer protrudes from the driving substrate to form pixel accommodation areas. The conductive isolation structures are arranged on the pixel definition layer and each surrounds one of the pixel accommodation areas. Each of the conductive isolation structures includes a main structure and a top structure located on an upper surface of the main structure and shielding the main structure. A portion of the top structure extending beyond the upper surface of the main structure is defined as an overhanging part. The sub-pixels are arranged in the pixel accommodation areas and are located between the conductive isolation structures. The encapsulating layer covers the sub-pixels and extends along sidewalls of the conductive isolation structures to form grooves surrounded by the encapsulating layer. An area directly below the overhanging part located in one of the grooves is defined as a shielding area.

In some embodiments, the driving substrate 10 is provided, and the pixel definition layer 20, the conductive isolation structure 40, the sub-pixels 30, and the encapsulating layer 50 are arranged on the driving substrate 10. The pixel definition layer 20 protrudes from the driving substrate 10 to form the pixel accommodation areas 210. The conductive isolation structures 40 are arranged on the pixel definition layer 20 and each surrounds one of the pixel accommodation areas 210. Each of the conductive isolation structures 40 includes the main structure 41 and the top structure 42 located on the upper surface of the main structure 41 and shielding the main structure 41. The portion of the top structure 42 extending beyond the upper surface of the main structure 41 is defined as the overhanging part 421. The sub-pixels 30 are arranged in the pixel accommodation areas 210 and are located between the conductive isolation structures 40. The encapsulating layer 50 covers the sub-pixels 30 and extends along the sidewalls of the conductive isolation structures 40 to form the grooves 510 surrounded by the encapsulating layer 50. The area directly below the overhanging part 421 located in one of the groove 510 is defined as the shielding area 422.

The producing operations of the pixel definition layer 20, the conductive isolation structures 40, the sub-pixels 30, and the encapsulating layer 50 are not described here, and may refer to the related art.

The embodiment is illustrated with the main structure 41 of the conductive isolation structure 40 including the conductive structure 411 and the intermediate structure 412 as an example. It should be understood that the main structure 41 of the conductive isolation structure 40 may also include only the conductive structure 411.

At block S20, at least partial of the plurality of insulating spherical structures are disposed in one of the grooves, and enabling the plurality of insulating spherical structures at least fill the shielding area to support the overhanging part.

In some embodiments, after the sub-pixels 30 completing a cycle process of the evaporation deposition, at least partial of the plurality of insulating spherical structures 60 are disposed in the groove 510, and enabling the plurality of insulating spherical structures 60 at least fill the shielding area 422 to support the overhanging part 421.

Whether the plurality of insulating spherical structures 60 are partially arranged in the groove 510 or entirely arranged in the groove 510 depends on the method for producing the insulating spherical structures 60 and the organic encapsulating layer 70.

In one embodiment, the plurality of insulating spherical structures 60 are all arranged in the groove 510.

The block S20 may include the following operations.

At block S21, the insulating spherical structures are disposed in the groove and an organic encapsulating layer is deposited. The organic encapsulating layer fills gaps between the insulating spherical structures and the grooves, and covers the encapsulating layer and the conductive isolation structures.

In some embodiments, before disposing the insulating spherical structures 60 in the groove 510, the number of the insulating spherical structures 60 that need to be arranged in a single groove 510 may be determined according to the volume of the groove 510 and the volume of the insulating spherical structure 60, so as to ensure that the plurality of insulating spherical structures 60 may at least fill the shielding area 422 and support the overhanging part 421.

The plurality of insulating spherical structures 60 are directionally filled into the groove 510 through the notch of the groove 510, and the groove 510 is filled by utilizing the rolling properties of the insulating spherical structures 60.

After the insulating spherical structures 60 are directionally filled into the groove 510, an organic material is injected into the groove 510 to completely fill the groove 510 and cover the encapsulating layer 50 and the conductive isolation structures. The organic material before curing is liquid and fluid. The liquid organic material may fill the gaps between the insulating spherical structures 60. Meanwhile, the insulating spherical structures 60 in the liquid organic material may also flow with the organic material and further deposit and level under the action of gravity. After a curing process, the position of the insulating spherical structures 60 will be fixed with the curing of the organic material. The whole groove 510 may be filled with the organic material and the insulating spherical structures 60. The insulating spherical structures 60 located in the shielding area 422 play a supporting role to the overhanging part 421. The cured organic material forms the organic encapsulating layer 70, and the side of the organic encapsulating layer 70 away from the driving substrate 10 is flattened, so as to facilitate the uniformity of subsequent coating of other encapsulating layers, thereby ensuring the encapsulation effect.

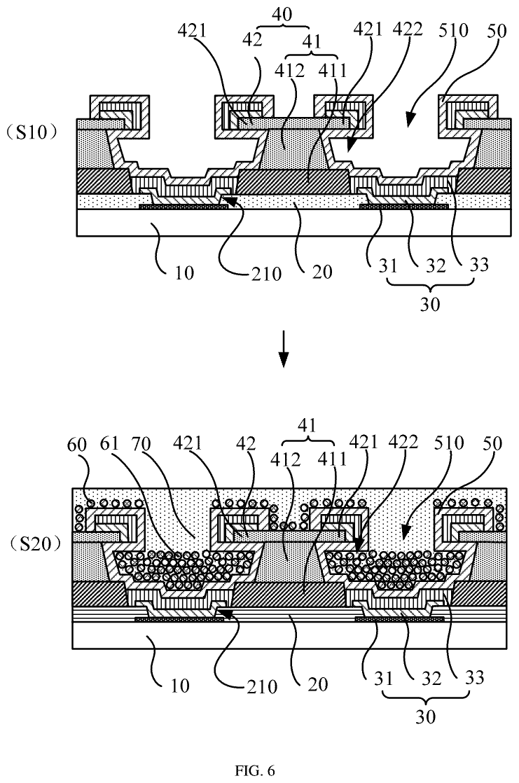

As shown in FIG. 3 and FIG. 6, FIG. 6 is a schematic structural view corresponding to block S10 and block S20 shown in FIG. 4 according to another embodiment of the present disclosure.

In the another embodiment, the plurality of insulating spherical structures 60 are partially arranged in the groove 510. The block S20 may include the following operations.

At block S22, a mixture of the insulating spherical structures and an organic material is filled into the groove, and the organic material is cured to form an organic encapsulating layer.

In some embodiments, the insulating spherical structures 60 are dispersed in the liquid organic material, and a proportion of the insulating spherical structures 60 in the organic material is controlled. In response to the proportion of the insulating spherical structures 60 in the organic material being too large, the thickness of the organic encapsulating layer 70 is easy to be too large, and it may not to be ensured the uniformity of the thickness of the organic encapsulating layer 70. In response to the proportion of the insulating spherical structures 60 in the organic material being too small, it may not be ensured that the insulating spherical structures 60 dispersed in the organic material may at least fill the shielding area 422 to support the overhanging part 421. The organic material is cured to form the organic encapsulating layer 70. The side of the organic encapsulating layer 70 away from the driving substrate 10 is flattened to ensure the uniformity of the coating of other encapsulating layers and meet the entire packaging requirements.

The insulating spherical structures 60 are dispersed in the organic encapsulating layer 70 and are filled in the groove 510 together with the organic encapsulating layer 70. As a result, some of the insulating spherical structures 60 are located in the groove 510 and some of the insulating spherical structures 60 are located outside the groove 510. Due to the deposition of the insulating spherical structures 60 in the uncured organic encapsulating layer 70, the insulating spherical structures 60 located above the notch of the groove 510 are deposited in the groove 510, enabling the density of the insulating spherical structures 60 accumulated in the groove 510 to be greater than the density of the insulating spherical structures 60 located outside the groove 510.

It should be noted that after the block S20, the method for producing the display panel may also include disposing an inorganic encapsulating layer 80 on the side of the organic encapsulating layer 70 away from the driving substrate 10.

In the above embodiments, the descriptions of each embodiment have their own emphasis. Parts that are not described in detail in a certain embodiment may be referred to the relevant descriptions of other embodiments.

The above descriptions are only embodiments of the present disclosure, and do not limit the protection scope of present disclosure. Any equivalent structure transformations or equivalent process transformations made by using the specifications and the drawings of the present disclosure, or directly or indirectly apply the specifications and the drawings of the present disclosure to other related technical fields, are all equally included within the protection scope of the present disclosure.

What is claimed is:

1. A display panel, comprising:
a driving substrate;
a pixel definition layer, arranged on the driving substrate and protruding from the driving substrate to form pixel accommodation areas;
conductive isolation structures, arranged on the pixel definition layer and each surrounding one of the pixel accommodation areas; wherein each of the conductive isolation structures comprises a main structure and a top structure located on an upper surface of the main structure and shielding the main structure, a portion of the top structure extending beyond the upper surface of the main structure is defined as an overhanging part;
sub-pixels, arranged in the pixel accommodation areas and located between the conductive isolation structures; and
an encapsulating layer, covering the sub-pixels and extending along sidewalls of the conductive isolation structures to form grooves surrounded by the encapsulating layer;
wherein an area directly below the overhanging part and located in one of the grooves is defined as a shielding area; the display panel comprises a plurality of insulating spherical structures, at least partial insulating spherical structures are arranged in the groove, and the plurality of insulating spherical structures at least fill the shielding area to support the overhanging part.

2. The display panel according to claim 1, wherein the encapsulating layer extends to an upper surface of the top structure; the display panel comprises an organic encapsulating layer filling gaps between the insulating spherical structures and the grooves, and covering the encapsulating layer and the conductive isolation structures.

3. The display panel according to claim 2, wherein the plurality of the insulating spherical structures located in the groove are accumulated to form an accumulation layer; an upper surface of the accumulation layer is lower than a surface of the encapsulating layer located on the upper surface of the top structure away from the pixel definition layer, and is higher than a surface of the encapsulating layer located on a lower surface of the top structure close to the pixel definition layer.

4. The display panel according to claim 3, wherein the plurality of insulating spherical structures are all located in the groove; or
the plurality of the insulating spherical structures are partially located in the groove, and the density of the insulating spherical structures located within the accumulation layer is greater than the density of the insulating spherical structures located outside the groove.

5. The display panel according to claim 2, wherein the display panel includes an inorganic encapsulating layer located on a side of the organic encapsulating layer away from the driving substrate.

6. The display panel according to claim 1, wherein the insulating spherical structures comprise alumina-based ceramic particles.

7. The display panel according to claim 1, wherein the diameter of each of the insulating spherical structures is smaller than a minimum depth of the groove and smaller than the width of a notch of the groove.

8. The display panel according to claim 7, wherein the minimum depth of the groove is a distance between a part of the encapsulating layer covering a lower surface of the overhanging part and a part of the encapsulating layer directly opposite the part of the encapsulating layer covering the lower surface of the overhanging part.

9. The display panel according to claim 1, wherein the shielding area accommodates at least one insulating spherical structure.

10. The display panel according to claim 1, wherein the main structure comprises a conductive structure, a side wall of the conductive structure is obliquely arranged with the overhanging part, and an inclination angle between the side wall of the conductive structure and a lower surface of the overhanging part is less than 90 degrees; or
the main structure comprises a conductive structure and an intermediate structure located between the conductive structure and the top structure; a side wall of the intermediate structure is obliquely arranged with the overhanging part, and an inclination angle between the side wall of the intermediate structure and a lower surface of the overhanging part is less than 90 degrees.

11. The display panel according to claim 10, wherein each of the sub-pixels comprises an anode, a light-emitting layer, and a cathode; the anode, the light-emitting layer, and the cathode are arranged in a stack, the cathode is arranged between the light-emitting layer and the encapsulating layer, and is arranged in contact with and conductive to the conductive structure.

12. The display panel according to claim 1, wherein each of the pixel accommodation areas accommodates at least one sub-pixel.

13. The display panel according to claim 1, wherein the top structure is in contact with the main structure, and an orthographic projection of the top structure on the driving substrate completely covers an orthographic projection of the main structure on the driving substrate.

14. The display panel according to claim 1, wherein the conductive isolation structures are arranged in an array.

15. A method for producing a display panel, configured to produce a display panel, comprising:
providing a driving substrate, wherein a pixel definition layer, conductive isolation structures, sub-pixels, and an encapsulating layer are arranged on the driving substrate; the pixel definition layer protrudes from the driving substrate to form pixel accommodation areas; the conductive isolation structures are arranged on the pixel definition layer and each surrounds one of the pixel accommodation areas; each of the conductive isolation structures comprises a main structure and a top structure located on an upper surface of the main structure and shielding the main structure; a portion of the top structure extending beyond the upper surface of the main structure is defined as an overhanging part; the sub-pixels are arranged in the pixel accommodation areas and are located between the conductive isolation structures; the encapsulating layer covers the sub-pixels and extends along sidewalls of the conductive isolation structures to form grooves surrounded by the encapsulating layer; an area directly below the overhanging part and located in one of the grooves is defined as a shielding area; and
disposing at least partial of a plurality of insulating spherical structures in one of the grooves, and enabling the plurality of insulating spherical structures at least fill the shielding area to support the overhanging part.

16. The method for producing the display panel according to claim 15, wherein the “disposing at least partial of a plurality of insulating spherical structures in one of the grooves, and enabling the plurality of insulating spherical structures at least fill the shielding area to support the overhanging part” comprises:
disposing all the plurality of insulating spherical structures in the groove and depositing an organic encapsulating layer, wherein the organic encapsulating layer fills gaps between the insulating spherical structures and the grooves, and covers the encapsulating layer and the conductive isolation structures; or
filling a mixture of the plurality of insulating spherical structures and an organic material into the grooves, and curing the organic material to form an organic encapsulating layer.

17. The method for producing the display panel according to claim 16, wherein the method comprises:
disposing an inorganic encapsulating layer on the side of the organic encapsulating layer away from the driving substrate.

18. The method for producing the display panel according to claim 15, wherein the insulating spherical structures comprise alumina-based ceramic particles.

19. The method for producing the display panel according to claim 15, wherein the diameter of each of the insulating spherical structures is smaller than a minimum depth of the groove and smaller than the width of a notch of the groove.

20. The method for producing the display panel according to claim 15, wherein the main structure comprises a conductive structure, a side wall of the conductive structure is obliquely arranged with the overhanging part, and an inclination angle between the side wall of the conductive structure and a lower surface of the overhanging part is less than 90 degrees; or
the main structure comprises a conductive structure and an intermediate structure located between the conductive structure and the top structure; a side wall of the intermediate structure is obliquely arranged with the overhanging part, and an inclination angle between the side wall of the intermediate structure and a lower surface of the overhanging part is less than 90 degrees.
